(19) United States
(12) Patent Application Publication
(10) Pub. No.: US 2026/0180425 A1
(43) Pub. Date: Jun. 25, 2026

(54) Gate drive control circuitry

(71) Applicant: Fast SiC Semiconductor Incorporated, Hsinchu City (TW)

(72) Inventors: Fu-Jen HSU, Hsinchu City (TW); Cheng-Tyng YEN, Hsinchu City (TW); Ting-Fu CHANG, Hsinchu City (TW); Hsiang-Ting HUNG, Hsinchu City (TW)

(21) Appl. No.: 19/000,399

(22) Filed: Dec. 23, 2024

(51) Int. Cl. H02M 1/08; H03K 17/0812

(52) U.S. Cl. CPC H02M 1/08; H03K 17/08122; H03K 2217/0063; H03K 2217/0081

(57) ABSTRACT

A gate drive control circuitry comprises a field-effect transistor, a driver, and a circuit. The field-effect transistor includes a gate terminal, a drain terminal, and a source terminal. The driver includes an input terminal configured to receive an input voltage from a controller, an output terminal connected to the gate terminal of the field-effect transistor, a ground terminal connected to the source terminal of the field-effect transistor, and a power supply terminal. The circuit is structured to supply a power to the driver through the power supply terminal of the driver, wherein the circuit is connected to at least one of a first path between the drain terminal and a drain pin and a second path between the input terminal and the controller.

### FIELD OF THE INVENTION

The invention relates to a circuit arrangement for supplying power to a gate driver in a switching circuit.

### BACKGROUND OF THE INVENTION

Key switch topologies, such as half-bridge and full-bridge, can be implemented using silicon (Si), silicon carbide (SiC), or gallium nitride (GaN) devices. Silicon IGBT (Insulated Gate Bipolar Transistor) technology, paired with Si anti-parallel diodes, is widely established in power applications for its reliable performance and affordability. However, newer wide bandgap (WBG) semiconductor technologies, such as SiC and GaN, offer distinct performance advantages, including greater efficiency, faster switching frequencies, and lower power losses-though these benefits come at a significantly higher cost.

SiC technology, in particular, is well-suited for high-power and high-temperature applications. This is due to SiC's physical advantages over conventional silicon, including a wide energy bandgap, high breakdown field strength, high electron drift velocity, and superior thermal conductivity. These properties allow SiC power switches to perform efficiently under extreme conditions, achieving much lower specific on-resistance than silicon-based devices. As a result, SiC unipolar devices are anticipated to replace silicon-based bipolar switches, such as IGBTs, and rectifiers in specific voltage ranges where these properties provide clear advantages.

However, the gate driver circuitry typically requires an independent power supply for driving the gate driver. This dependence introduces several issues, including increased circuit complexity, the need for additional wiring and components, and potential reliability concerns due to external power fluctuations. Furthermore, the necessity for an external power supply complicates system design and may lead to higher costs and space requirements.

### SUMMARY OF THE INVENTION

This disclosure describes techniques for supplying power to the gate driver by introducing a circuit that sources power directly from the switching circuit itself, thereby enhancing reliability and reducing dependence on external high-voltage sources.

In some examples, a gate drive control circuitry comprises a field-effect transistor, a driver, and a circuit. The field-effect transistor includes a gate terminal, a drain terminal, and a source terminal. The driver includes an input terminal configured to receive an input voltage from a controller, an output terminal connected to the gate terminal of the field-effect transistor, a ground terminal connected to the source terminal of the field-effect transistor, and a power supply terminal. The circuit is structured to supply a power to the driver through the power supply terminal of the driver, wherein the circuit is connected to at least one of a first path between the drain terminal and a drain pin and a second path between the input terminal and the controller.

In some examples, an integrated metal-oxide-semiconductor field-effect transistor (MOSFET) component is described. The integrated MOSFET component comprises a field-effect transistor, a driver, and a circuit. The field-effect transistor includes a gate terminal, a drain terminal, and a source terminal. The drain terminal and the source terminal are connected to a drain pin and a source pin of the component. The driver includes an input terminal configured to receive an input voltage from a controller, an output terminal connected to the gate terminal of the field-effect transistor, a ground terminal connected to the source terminal of the field-effect transistor, and a power supply terminal. The circuit is structured to supply a power to the driver through the power supply terminal of the driver, wherein the circuit is connected to at least one of a first path between the drain terminal and a drain pin of the component and a second path between the input terminal and the controller.

### BRIEF DESCRIPTION OF THE DRAWINGS

Example embodiments of the present disclosure will be described with reference to the accompanying drawings briefly described below.

FIG. 1 is a circuit block diagram of a first exemplary embodiment of the present disclosure.

FIG. 2 is a circuit block diagram of a second exemplary embodiment of the present disclosure.

FIG. 3 is a circuit block diagram of a third exemplary embodiment of the present disclosure.

FIG. 4 is a circuit block diagram of a fourth exemplary embodiment of the present disclosure.

FIG. 5 is a circuit block diagram of a fifth exemplary embodiment of the present disclosure.

### DETAILED DESCRIPTION

Prior to turning to the figures, which illustrate exemplary embodiments in detail, it should be understood that this disclosure is not limited to the specific details or methodologies described or shown in the figures. Additionally, the terminology used herein is for descriptive purposes only and should not be considered limiting.

Throughout the specification and claims, the meanings provided below are not intended to strictly limit the terms but to serve as illustrative examples. The terms “a,” “an,” and “the” should be understood to include plural references, and “in” should be interpreted as including “in” and “on.” The phrase “in an embodiment” or “in an example,” as used herein, does not necessarily refer to the same embodiment or example, although it may.

A circuit for use on power semiconductor devices that is controlled so as to modulate the flow of electrical current from one or more electrical sources to one or more electrical loads is described. The power semiconductor device may be a switch that is made from a semiconductor material such as silicon (Si), silicon carbide (SiC), Gallium Nitride (GaN) and other Wide Bandgap materials (WBGs). The switch may be an insulated gate bipolar transistor (IGBT), a metal-oxide-semiconductor field-effect transistor (MOSFET), a junction gate field-effect transistor (JFET) or other power semiconductor devices.

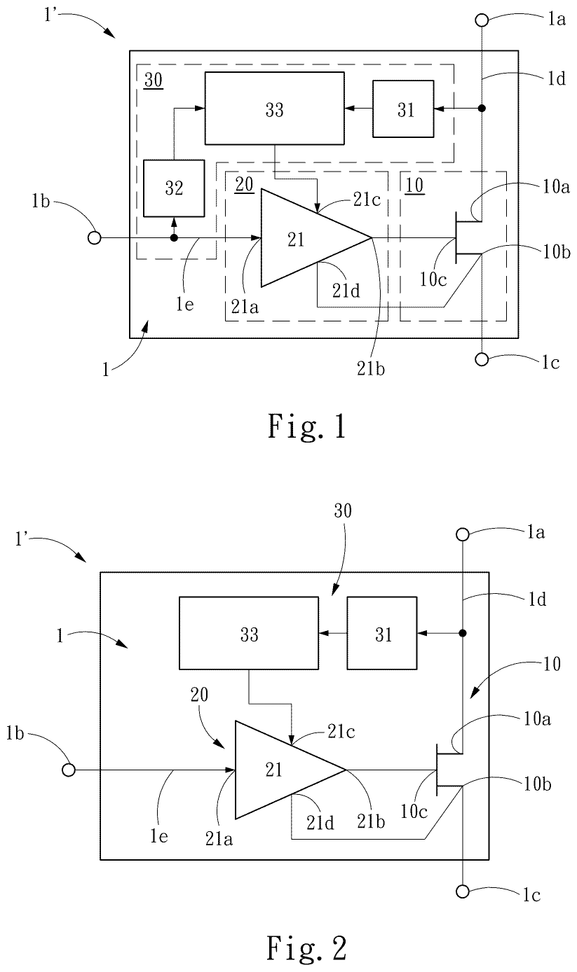

FIG. 1 is a circuit block diagram illustrating the first exemplary embodiment of a switching circuit 1 and its associated driving circuitry, commonly used in power electronic applications like power conversion devices. The switching circuit 1 can serve multiple functions, such as being part of an inverter, part of a solid state relay, part of a power factor correction device, part of a power supply for a DC/DC conversion circuit, part of a DC/AC conversion circuit (expandable into, a half-bridge circuit, a full-bridge circuit, a three-phase inverter, etc.), or as part of a motor control device. In an example, the circuitry may be a high-side drive circuitry or a part of a high-side drive circuitry.

The switching circuit 1 in FIG. 1 may be a packaged IC 1′. The switching circuit 1 comprises a switching element 10, a gate driver circuit 20, and a power conversion circuit 30. The switching element 10 may be a field-effect transistor, such as a SiC MOSFET. The switching circuit 1 may be implemented as part of an integrated transistor component, such as a three-pin MOSFET component. In one example, the switching element 10, the gate driver circuit 20, and the power conversion circuit 30 may be formed on a SiC wafer. Alternatively or additionally, the switching element 10, the gate driver circuit 20, and the power conversion circuit 30 may be integrated into a package to form a compact and unified component.

The packaged IC 1′ includes three out pins. The out pins include a drain pin 1a, an input pin 1b and a source pin 1c. The switching element 10 comprises a drain terminal 10a, a source terminal 10b, and a gate terminal 10c. The drain terminal 10a and the source terminal 10b may be connected to a voltage bus and further connected to a load. The gate terminal 10c is connected to the gate driver circuit 20 and configured to receive a gate drive signal from the gate driver circuit 20.

The gate driver circuit 20 includes a gate driver 21 functioning as an amplifier to generate the gate drive signal required to control the switching element 10. The gate driver 21 may comprise various electronic components such as a diode device, a capacitor device, a level shifter circuit, a resistive device, a logic device, a control switch and a driver, depending on design requirements. For the sake of convenience in description, FIG. 1 and the subsequent figures illustrate only a part of a pin configuration in the gate driver 21, including an input terminal 21a, an output terminal 21b, a power supply terminal (Vcc) 21c and a ground terminal 21d. The input terminal 21a is connected to a controller to receive a driver control signal to regulate the operation of the gate driver 21, which may be a PWM signal. The driver control signal is generated by using, for example, a microcontroller or similar IC chip. The gate driver circuit 20 plays roles of, for example, a voltage level converting function, a timing adjusting function, a noise cancelling function, and a protecting function for the driver control signal.

The output terminal 21b is connected to the gate terminal 10c of the switching element 10 and configured to deliver the gate drive signal to turn the switching element 10 on or off. The ground terminal 21d is connected to between the source terminal 10b of the switching element 10 and the source pin 1c of the switching element 10 (or the ground terminal 21d is connected to the source terminal 10b). The power supply terminal 21c is connected to the power conversion circuit 30.

The power conversion circuit 30 is configured to deliver power necessary for starting and operating gate driver 21. In the example of FIG. 1, the power conversion circuit 30 includes a first power extraction circuit 31, a second power extraction circuit 32, and a voltage regulator 33. The first power extraction circuit 31 is connected to a first current path 1d between the drain terminal 10a of the switching element 10 and the drain pin 1a of the switching circuit 1, for receiving power from the first current path 1d. The second power extraction circuit 32 is connected to a second current path 1e between the input terminal 21a of the gate driver 21 and the input pin 1b of the switching circuit 1, for receiving power from the second current path 1e. In the example, the first and second power extraction circuits 31, 32 may be independently a voltage conversion component. The voltage regulator 33 is connected to the first and second power extraction circuits 31, 32 and configured to receive power from the first and second power extraction circuits 31, 32 and output a regulated power to the power supply terminal 21c of the gate driver 21. The regulated power is regulated for the purpose of driving the gate driver 21.

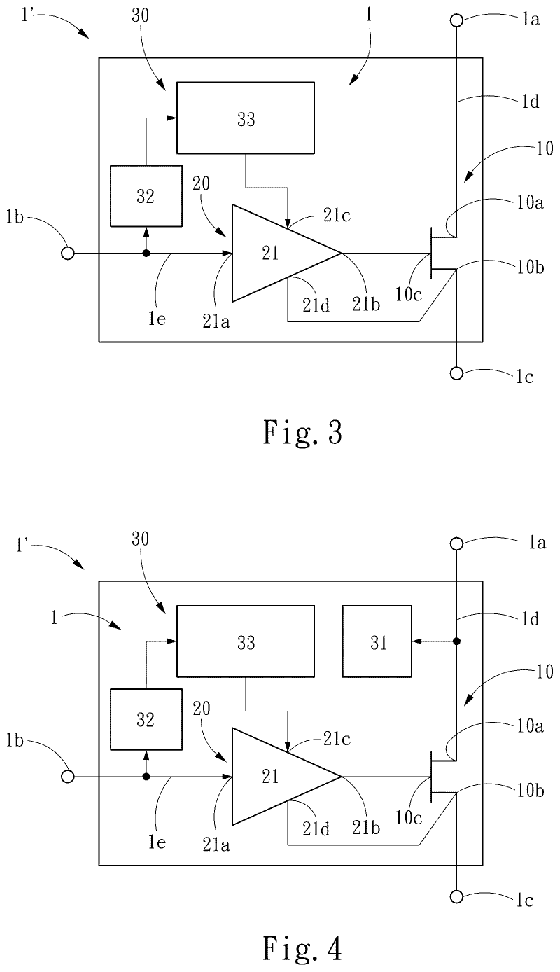

In one example, the power conversion circuit 30 is possible to connect to either the first current path 1d or the second current path 1e. As shown in FIG. 2, the power conversion circuit 30 includes the first power extraction circuit 31 and the voltage regulator 33, meaning that power for driving the gate driver 21 is sourced from the first current path 1d. Conversely, in FIG. 3, the power conversion circuit 30 includes the second power extraction circuit 32 and the voltage regulator 33, in which example the power for driving the gate driver 21 sources from the second current path 1e. In some examples, the selection of the current path may depend on the power supply requirements of the gate driver 21.

The output stage of switching circuit 1 is typically designed to provide a higher voltage output than that of the input stage. Accordingly, the configuration in FIG. 2 is suitable for supplying start-up power to gate driver 21, while the configuration in FIG. 3 is suitable for providing operational power to gate driver 21. In one example, the first power extraction circuit 31 may be a buck converter or similar circuit designed to lower the voltage, as the output stage operates at ahigh voltage. The second power extraction circuit 32 may be a boost converter or a circuit designed to increase voltage, as the input stage operates at a lower voltage, such as 3V or 5V. Nevertheless, the power conversion circuit 30 in FIG. 2 can still serve as the start-up power supply, and the power conversion circuit 30 in FIG. 3 can still serve as the operational power supply for gate driver 21, provided that the appropriate power extraction circuit is selected.

FIG. 4 illustrates a variation of the example shown in FIG. 1. In this configuration of the power conversion circuit 30, the first power extraction circuit 31 is directly connected to the power supply terminal 21c rather than to the voltage regulator 33. Here, the first power extraction circuit 31 supplies start-up power to gate driver 21, while a combination of the second power extraction circuit 32 and the voltage regulator 33 supplies operational power. The operational power has a voltage lower than that of the start-up power.

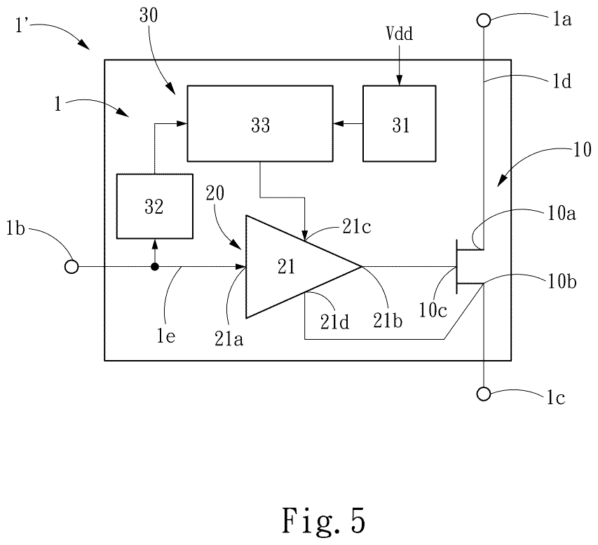

FIG. 5 illustrates another variation of the example of FIG. 1. In this example, the first power extraction circuit 31 is not connected to the first current path 1d. Instead, the first power extraction circuit 31 is connected to an electrical power source, which may be an external device disposed outside the switching circuit 1.

1. A gate drive control circuitry, comprising:
a field-effect transistor including a gate terminal, a drain terminal and a source terminal;
a driver including an input terminal configured to receive an input voltage from a controller, an output terminal connected to the gate terminal of the field-effect transistor, a ground terminal connected to the source terminal of the field-effect transistor, and a power supply terminal; and
a circuit structured to supply power to the driver through the power supply terminal of the driver, wherein the circuit is connected to at least one of the following to source power for driving the driver:
a first path between the drain terminal and a drain pin; and
a second path between the input terminal and the controller,
wherein the input terminal is different from the power supply terminal, and the ground terminal is not directly coupled with the power supply terminal.

2. The gate drive control circuitry of claim 1, wherein the circuit includes:
a power extraction circuit configured to extract power from the first path; and
a voltage regulator configured to regulate an input power from the power extraction circuit and output a regulated power to the power supply terminal of the driver.

3. The gate drive control circuitry of claim 1, wherein the circuit includes:
a power extraction circuit configured to extract power from the second path; and
a voltage regulator configured to regulate an input power from the power extraction circuit and output a regulated power to the power supply terminal of the driver.

4. The gate drive control circuitry of claim 1, wherein the circuit includes:
a first power extraction circuit configured to extract power from the first path;
a second power extraction circuit configured to extract power from the second path; and
a voltage regulator connected with the first power extraction circuit and the second power extraction circuit, wherein the voltage regulator is configured to:
regulate a first input power from the first power extraction circuit and output a first regulated power to the power supply terminal of the driver to drive the driver; and
regulate a second input power from the second power extraction circuit and output a second regulated power to the power supply terminal of the driver to operate the driver.

5. The gate drive control circuitry of claim 4, wherein a voltage of the first regulated power is higher than that of the second regulated power.

6. The gate drive control circuitry of claim 4, wherein the circuit includes:
a voltage converting circuit connected to the first path or the second path, wherein the voltage converting circuit extracts power from the first path or the second path; and
a voltage regulator connected to the voltage converting circuit, wherein the voltage regulator regulates an input power from the voltage converting circuit and outputs a regulated power to the power supply terminal of the driver.

7. The gate drive control circuitry of claim 6, wherein the voltage converting circuit is a buck converter or a boost converter.

8. The gate drive control circuitry of claim 6, wherein the voltage regulator is a low-dropout regulator.

9. The gate drive control circuitry of claim 1, wherein the circuit includes:
a first power extraction circuit configured to extract power from an external power source;
a second power extraction circuit configured to extract power from the second path; and
a voltage regulator connected with the first power extraction circuit and the second power extraction circuit, wherein the voltage regulator is configured to:
regulate a first input power from the first power extraction circuit and output a first regulated power to the power supply terminal of the driver to drive the driver; and
regulate a second input power from the second power extraction circuit and output a second regulated power to the power supply terminal of the driver to operate the driver.

10. The gate drive control circuitry of claim 1, wherein the circuit includes:
a first power extraction circuit configured to extract power from the first path and output a driving power to the power supply terminal of the driver to drive the driver;
a second power extraction circuit configured to extract power from the second path; and
a voltage regulator connected with the second power extraction circuit, wherein the voltage regulator is configured to: regulate a second input power from the second power extraction circuit and output a second regulated power to the power supply terminal of the driver to operate the driver.

11. The gate drive control circuitry of claim 1, wherein the gate drive control circuitry is a high-side drive circuitry.

12. An integrated metal-oxide-semiconductor field-effect transistor (MOSFET) component, comprising:
a field-effect transistor including a gate terminal, a drain terminal and a source terminal, wherein the drain terminal and the source terminal are connected to a drain pin and a source pin of the component;
a driver including an input terminal connected to an input pin of the component and configured to receive an input voltage from a controller, an output terminal connected to the gate terminal of the field-effect transistor, a ground terminal connected to the source terminal of the field-effect transistor, and a power supply terminal; and
a circuit structured to supply a power to the driver through the power supply terminal of the driver, wherein the circuit is connected to at least one of the following to source power for driving the driver:
a first path between the drain terminal and the drain pin of the component; and
a second path between the input terminal and the controller,
wherein the input terminal is different from the power supply terminal, and the ground terminal is not directly coupled with the power supply terminal.

13. The MOSFET component of claim 12, wherein the field-effect transistor, the driver and the circuit are integrated in a package.

14. The MOSFET component of claim 12, wherein the field-effect transistor, the driver and the circuit are formed on a SiC wafer.

15. The MOSFET component of claim 12, wherein the component is a three-pin MOSFET component.
